(19) United States
(12) Patent Application Publication
(10) Pub. No.: US 2026/0032948 A1
(43) Pub. Date: Jan. 29, 2026

(54) SEMICONDUCTOR DEVICE

(71) Applicant: ROHM CO., LTD., Kyoto (JP)

(72) Inventor: Yusuke SHIMIZU, Kyoto-shi (JP)

(73) Assignee: ROHM CO., LTD., Kyoto (JP)

(21) Appl. No.: 19/343,672

(22) Filed: Sep. 29, 2025

Related U.S. Application Data
(63) Continuation of application No. PCT/JP2024/010860, filed on Mar. 19, 2024.

(30) Foreign Application Priority Data
Mar. 30, 2023 (JP) 2023-055785

(51) Int. Cl. H10D 30/65; H10D 1/47; H10D 62/10; H10D 62/60; H10D 64/00; H10D 84/00

(52) U.S. Cl. CPC H10D 30/655; H10D 1/47; H10D 62/102; H10D 62/116; H10D 62/126; H10D 62/60; H10D 64/112; H10D 84/151

(57) ABSTRACT

A semiconductor device includes: a semiconductor chip having a principal surface, a drift region formed in the semiconductor chip, a drain region, body and a source region, a gate electrode facing a channel region formed in the body region through a gate insulating film, a plurality of insulating isolation structures embedded in a surface layer portion of the principal surface of the semiconductor chip along a first direction between the body region and the drain region, a first active area sandwiched between the adjacent insulating isolation structures in a second direction, and a gate field plate extending from the gate electrode to a region on the insulating isolation structure, wherein the gate insulating film includes a first portion formed on the channel region and a second portion integrally extending from the first portion toward the drain region, formed on the drift region, and having a second thickness larger than a first thickness of the first portion.

### CROSS REFERENCE TO RELATED APPLICATIONS

The present application is a bypass continuation application of International Patent Application No. PCT/JP2024/010860 filed on Mar. 19, 2024, which corresponds to Japanese Patent Application No. 2023-055785 filed on Mar. 30, 2023 with the Japan Patent Office, and the entire disclosures of these applications are incorporated herein by reference.

### TECHNICAL FIELD

The present disclosure relates to a semiconductor device.

### BACKGROUND ART

For example, Patent Literature 1 (Japanese Patent Application Publication No. 2023-017388) discloses a semiconductor device including a drain region formed in a surface layer portion of a drift region, a back gate region formed in a surface layer portion of the drift region, a source region formed in a surface layer portion of the back gate region, a back gate contact region formed in a surface layer portion of the back gate region, a gate insulating film formed on a first principal surface of a semiconductor chip, a gate electrode formed on the gate insulating film and facing a channel region formed in the back gate region, and an impurity region formed across an n-type side portion of the source region and a p-type side portion of the back gate contact region.

### BRIEF DESCRIPTION OF DRAWINGS

FIG. 1 is a schematic plan view of a semiconductor device according to a preferred embodiment of the present invention.

FIG. 2 is an enlarged view of region II illustrated in FIG. 1.

FIG. 3 is a perspective view of a gate electrode in FIG. 2.

FIG. 4 is a schematic perspective view of an LDMOSFET.

FIG. 5 is a cross-sectional view taken along line V-V illustrated in FIG. 4.

FIG. 6 is a cross-sectional view taken along line VI-VI illustrated in FIG. 4.

FIG. 7 is a diagram illustrating a state in which a current flows in a first active area.

FIG. 8 is a diagram illustrating a state in which a current flows in a second active area.

FIG. 9 is a diagram illustrating an example of a characteristic structure that can be introduced into the semiconductor device.

FIG. 10 is a diagram illustrating an example of a characteristic structure that can be introduced into the semiconductor device.

FIG. 11 is a diagram illustrating an example of a characteristic structure that can be introduced into the semiconductor device.

FIG. 12 is a diagram illustrating an example of a characteristic structure that can be introduced into the semiconductor device.

FIG. 13 is a diagram illustrating an example of a characteristic structure that can be introduced into the semiconductor device.

FIG. 14 is a diagram illustrating an example of a characteristic structure that can be introduced into the semiconductor device.

FIG. 15 is a diagram illustrating an example of a characteristic structure that can be introduced into the semiconductor device.

FIG. 16 is a diagram illustrating an example of a characteristic structure that can be introduced into the semiconductor device.

FIG. 17 is a diagram illustrating an example of a characteristic structure that can be introduced into the semiconductor device.

FIG. 18 is a diagram illustrating an example of a characteristic structure that can be introduced into the semiconductor device.

FIG. 19 is a diagram illustrating an example of a characteristic structure that can be introduced into the semiconductor device.

FIG. 20 is a diagram illustrating an example of a characteristic structure that can be introduced into the semiconductor device.

FIG. 21 is a diagram illustrating an example of a characteristic structure that can be introduced into the semiconductor device.

FIG. 22 is a diagram illustrating an example of a characteristic structure that can be introduced into the semiconductor device.

FIG. 23 is a diagram illustrating an example of a characteristic structure that can be introduced into the semiconductor device.

FIG. 24 is a diagram illustrating an example of a characteristic structure that can be introduced into the semiconductor device.

### DESCRIPTION OF EMBODIMENTS

Next, a preferred embodiment of the present disclosure will be described in detail with reference to the attached drawings.

### <Basic Structure of Semiconductor Device 1>

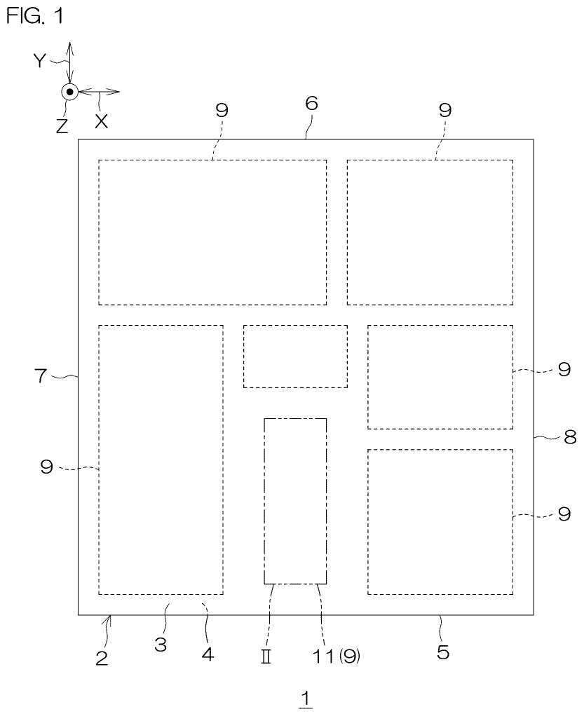

First, a basic structure of a semiconductor device 1 will be described with reference to FIGS. 1 to 6.

FIG. 1 is a schematic plan view of the semiconductor device 1 according to a preferred embodiment of the present invention.

The semiconductor device 1 includes a semiconductor chip 2 formed in a rectangular parallelepiped shape. The semiconductor chip 2 forms the outer shape of the semiconductor device 1, and is, for example, a structure in which a single crystal semiconductor material is formed in a chip shape (rectangular parallelepiped shape). The semiconductor chip 2 is formed of a semiconductor material such as Si or SiC.

The semiconductor chip 2 has a first principal surface 3 on one side, a second principal surface 4 on the other side, and first to fourth side surfaces 5 to 8 connecting the first principal surface 3 and the second principal surface 4. The first to fourth side surfaces 5 to 8 include a first side surface 5, a second side surface 6, a third side surface 7, and a fourth side surface 8. The first side surface 5 and the second side surface 6 extend in the first direction X and face each other in the second direction Y orthogonal to the first direction X. The third side surface 7 and the fourth side surface 8 extend in the second direction Y and face each other in the first direction X.

The first principal surface 3 and the second principal surface 4 are formed in a quadrangular shape in a plan view (hereinafter, simply referred to as “plan view”) when viewed from the third direction Z (normal direction of the first principal surface 3 and the second principal surface 4). The first principal surface 3 may be referred to as a device surface on which a functional device is formed. The second principal surface 4 may be referred to as a non-device surface on which no functional device is formed. A plurality of device regions 9 are formed on the first principal surface 3. The number and arrangement of the plurality of device regions 9 are arbitrary. The plurality of device regions 9 may include a functional device formed using the surface layer portion of the first principal surface 3. The functional device may include, for example, at least one of a semiconductor switching device, a semiconductor rectifying device, and a passive device. The functional device may include, for example, a circuit network in which at least two of a semiconductor switching device, a semiconductor rectifying device, and a passive device are combined.

The semiconductor switching device may include, for example, at least one of a metal-oxide-semiconductor field-effect transistor (MOSFET), a bipolar junction transistor (BJT), an insulated gate bipolar transistor (IGBT), and a junction field effect transistor (JFET). The semiconductor rectifying device may include, for example, at least one of a pn junction diode, a pin junction diode, a Zener diode, a Schottky barrier diode, and a fast recovery diode. The passive device may include, for example, at least one of a resistor, a capacitor, and an inductor.

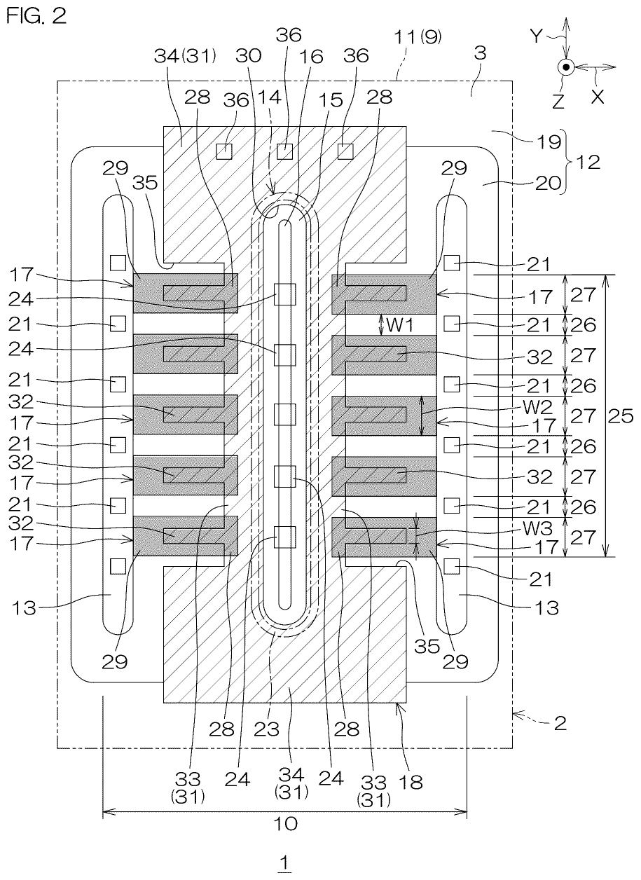

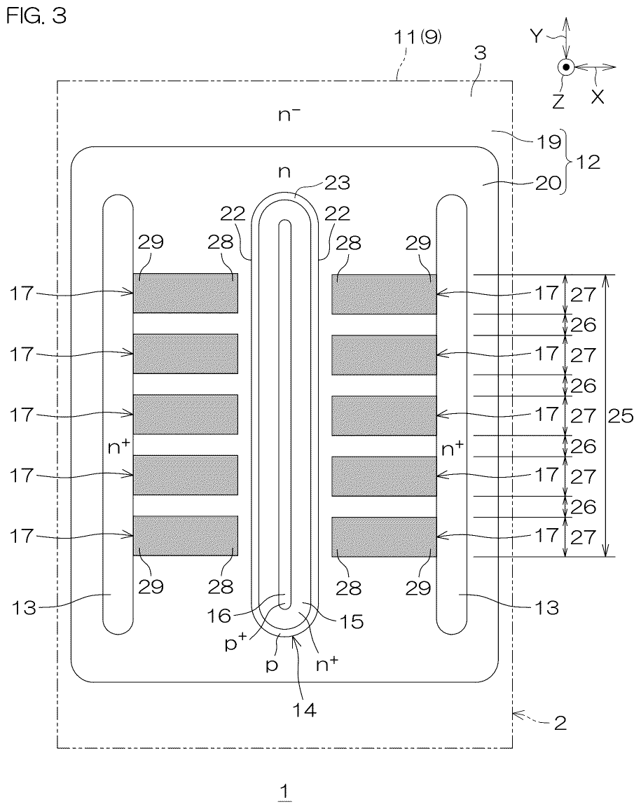

FIG. 2 is an enlarged view of region II illustrated in FIG. 1. FIG. 3 is a perspective view of a gate conductor 18 in FIG. 2. In FIGS. 2 and 3, for clarity, the gate conductor 18 is indicated by hatching, and an insulating isolation structure 17 is indicated by gray fill.

Referring to FIGS. 2 and 3, the semiconductor device 1 includes an LDMOS region 11 in which a lateral double diffused MOSFET (LDMOSFET) 10 is formed among the plurality of device regions 9.

The LDMOS region 11 includes a drift region 12, a drain region 13, a body region 14, a source region 15, a body contact region 16, the insulating isolation structure 17, and the gate conductor 18.

In this form, the drift region 12 is a diffusion region of n-type impurities. The drift region 12 may be referred to as an n-type drift region. The drift region 12 is a region for reducing the surface electric field in the LDMOSFET 10, and may be referred to as an n-type RESURF (Raised SURface Field) layer. The drift region 12 is formed over the entire surface layer portion of the first principal surface 3 of the semiconductor chip 2.

The drift region 12 includes a first drift region 19 and a second drift region 20. The first drift region 19 is formed over the entire surface layer portion of the first principal surface 3, and the second drift region 20 is selectively formed on the surface layer portion of the first drift region 19. Since the second drift region 20 is formed in a well shape in the first drift region 19, the second drift region may be referred to as an n-type well region.

The n-type impurity concentration of the first drift region 19 may be, for example, 1.0×10¹⁴ cm⁻³ or more and 1.0×10¹⁶ cm⁻³ or less. The n-type impurity concentration of the second drift region 20 is higher than the n-type impurity concentration of the first drift region 19. The n-type impurity concentration of the second drift region 20 may be, for example, 1.0×10¹⁵ cm⁻³ or more and 1.0×10¹⁷ cm⁻³ or less.

Since the n-type impurity concentration of the first drift region 19 is lower than the n-type impurity concentration of the second drift region 20, the first drift region 19 may be referred to as a low-concentration drift region (low-concentration RESURF layer) in the relative relationship with the second drift region 20. Conversely, the second drift region 20 may be referred to as a high-concentration drift region (high-concentration RESURF layer) in the relative relationship with the first drift region 19. In addition, the first drift region 19 and the second drift region 20 may be referred to as a high resistance drift region and a low resistance drift region, respectively, focusing on the difference in resistance value caused by the difference in n-type impurity concentration.

In this form, the drain region 13 is a diffusion region of n-type impurities having an n-type impurity concentration higher than that of the drift region 12. The drain region 13 may be referred to as an n-type drain region. The n-type impurity concentration of the drain region 13 may be, for example, 1.0×10¹⁶ cm⁻³ or more and 5.0×10¹⁷ cm⁻³ or less.

The drain region 13 is formed in a surface layer portion of the second drift region 20. The drain region 13 is formed in a band shape extending along the second direction Y in a plan view. In this form, the pair of drain regions 13 are spaced apart in the first direction X and extends parallel to each other in the second direction Y. Referring to FIG. 2, a drain contact 21 connected to the drain region 13 is formed in the drain region 13. In this form, the plurality of drain contacts 21 are arrayed at intervals in the second direction Y. Each of the plurality of drain contacts 21 is located at a position adjacent to the first active area 26 in the first direction X.

In this form, the body region 14 is a p-type impurity diffusion region. The body region 14 may be referred to as a p-type body region. The body region 14 is formed with a space from the pair of drain regions 13. The body region 14 is formed in a region sandwiched between the pair of drain regions 13. The body region 14 may be surrounded by the second drift region 20. Referring to FIG. 3, in this form, the body region 14 is in contact with the second drift region 20 and forms a boundary 22 with the second drift region 20, but may be formed with a space inside from the second drift region 20. In this case, a part of the first drift region 19 may be formed between the body region 14 and the second drift region 20. Since the body region 14 is formed in a well shape in the first drift region 19, the body region may be referred to as a p-type well region.

The body region 14 is formed in a band shape extending along the second direction Y in a plan view. Thereby, the body region 14 forms the linear boundary 22 extending in the second direction Y with the drift region 12. The body region 14 has a width in the first direction X wider than that of each drain region 13. The body region 14 may be referred to as a p-type back gate region to which the back gate voltage of the LDMOSFET 10 is applied.

In this form, the source region 15 is a diffusion region of n-type impurities having an n-type impurity concentration higher than that of the drift region 12. The source region 15 may be referred to as an n-type source region. The n-type impurity concentration of the source region 15 may be, for example, 1.0×10¹⁶ cm⁻³ or more and 5.0×10¹⁷ cm⁻³ or less.

The source region 15 is formed in a surface layer portion of the body region 14. The source region 15 is formed in an inner region of the body region 14 spaced inward from an outer peripheral edge of the body region 14. An annular region in a plan view between the source region 15 and the body region 14 is a channel region 23 in which a channel of the LDMOSFET 10 is formed. The source region 15 is formed in a band shape extending along the second direction Y in a plan view.

In this form, the body contact region 16 is a p-type impurity diffusion region having a p-type impurity concentration higher than that of the body region 14. The body contact region 16 may be referred to as a p-type body contact region. The p-type impurity concentration of the body contact region 16 may be, for example, 1.0×10¹⁶ cm⁻³ or more and 5.0×10¹⁷ cm⁻³ or less.

The body contact region 16 is formed in a surface layer portion of the body region 14. The body contact region 16 is formed in an inner region of the source region 15 spaced inward from an outer peripheral edge of the source region 15. The body contact region 16 is formed in a band shape extending along the second direction Y in a plan view.

Referring to FIG. 2, a source contact 24 connected to the source region 15 and the body contact region 16 is formed in the source region 15 and the body contact region 16. In this form, the plurality of source contacts 24 are arrayed at intervals in the second direction Y. Each source contact 24 extends across the source region 15 and the body contact region 16, and is connected to both the source region 15 and the body contact region 16.

In this form, a region sandwiched between the body region 14 and the drain region 13 in the first direction X is an active area 25 through which the current of the LDMOSFET 10 flows. The insulating isolation structure 17 is formed in the active area 25. In this form, the plurality of insulating isolation structures 17 are arrayed at intervals in the second direction Y. Thereby, the active area 25 may be isolated into the first active area 26 sandwiched between the adjacent insulating isolation structures 17 and the second active area 27 covered with each insulating isolation structure 17. In FIGS. 2 and 3, the plurality of first active areas 26 and the plurality of second active areas 27 are alternately arrayed in the second direction Y. The plurality of insulating isolation structures 17 are physically isolated and independent from each other.

Each insulating isolation structure 17 is formed in a band shape crossing the active area 25 in the first direction X from the body region 14 toward the drain region 13. More specifically, the insulating isolation structure is formed in a rectangular shape having a long side along the first direction X and a short side along the second direction Y. Thereby, the width W1 of the first active area 26 in the second direction Y is constant. In addition, the width W2 of the second active area 27 (insulating isolation structure 17) in the second direction Y is constant. The width W1 may be narrower than the width W2. For example, the width W1 may be 0.1 μm or more and 5 μm or less, and the width W2 may be 0.2 μm or more and 2 μm or less.

Referring to FIG. 3, in this form, each insulating isolation structure 17 has a first end portion 28 in the first direction X and a second end portion 29 on the opposite side. The first end portion 28 is an end portion on the body region 14 side (source region 15 side). The first end portion 28 may be spaced apart from the body region 14 in the first direction X and face the body region 14 with a part of the second drift region 20 interposed therebetween. The second end portion 29 is an end portion on the drain region 13 side. The second end portion 29 may be in contact with the drain region 13. As a matter of course, the first end portion 28 may be in contact with the body region 14, and the second end portion 29 may be spaced apart from the drain region 13 in the first direction X and face the body region 14 with a part of the second drift region 20 interposed therebetween.

Referring to FIG. 2, the gate conductor 18 is formed in an annular shape surrounding the source region 15 and the body contact region 16 in a plan view. In FIG. 2, the gate conductor 18 is hatched for clarity. A source opening 30 for exposing the source region 15 and the body contact region 16 is formed in a central portion of the gate conductor 18. The source opening 30 is formed in an elongated shape along the second direction Y, and integrally exposes the source region 15 and the body contact region 16.

The gate conductor 18 includes a gate electrode 31 covering the channel region 23 and a gate field plate 32 integrally extending from the gate electrode 31.

The gate electrode 31 covers the source region 15, the channel region 23 (body region 14), and the second drift region 20 in this order from the inside to the outside. The gate electrode 31 includes a pair of controlling portions 33 facing each other with a space therebetween in the first direction X with the source opening 30 interposed therebetween, and a pair of contact portions 34 connecting both end portions of the pair of controlling portions 33 in the second direction Y.

In this form, a pair of island-shaped contact portions 34 are integrally connected to both end portions of a pair of linear controlling portions 33 parallel to each other along the second direction Y. Each of the contact portions 34 protrudes outward in the first direction X with respect to the pair of controlling portions 33, and is formed to be wider than the pair of controlling portions 33. In other words, each controlling portion 33 is set back inward with respect to the end edge of each contact portion 34 in the first direction X. Thereby, a recess portion 35 adjacent to each controlling portion 33 is formed between the pair of contact portions 34 in the second direction Y.

A gate contact 36 to which a gate voltage is applied is formed in the contact portion 34. In this form, the plurality of gate contacts 36 are arrayed at intervals in the first direction X.

The gate field plate 32 extends from the gate electrode 31 to a region on the insulating isolation structure 17. In this form, the plurality of gate field plates 32 are arrayed at intervals in the second direction Y. The plurality of gate field plates 32 are formed in a comb shape protruding from the gate electrode 31 to the opposite side of the source opening 30 as a whole.

Each gate field plate 32 is provided in each insulating isolation structure 17 in a one-to-one relationship. A recess portion 35 is formed in the gate electrode 31, and a part or all of the plurality of gate field plates 32 are formed in the recess portion 35. The recess portion 35 is effectively used as a space for the gate field plate 32, and the width of the gate conductor 18 as a whole in the first direction X can be narrowed. Thereby, the area of the active area 25 can be reduced.

Each gate field plate 32 is formed in a band shape extending in the first direction X. More specifically, the insulating isolation structure is formed in a rectangular shape having a long side along the first direction X and a short side along the second direction Y. Thus, each gate field plate 32 has a constant width W3 in the second direction Y.

The gate conductor 18 is formed of polysilicon. In this form, in the gate conductor 18, the gate electrode 31 is formed of n-type polysilicon, and the gate field plate 32 is formed of i-type polysilicon. For example, the gate conductor 18 in which an n-type portion and an i-type portion are isolated can be formed by depositing a polysilicon material to which no impurity is added by CVD or the like and then partially introducing an n-type impurity into a formation region of the gate electrode 31.

In the gate conductor 18, both the gate electrode 31 and the gate field plate 32 may be formed of n-type polysilicon. In this case, the on-resistance can be reduced by the charge accumulation effect of the n-type polysilicon.

On the other hand, in the gate conductor 18, the gate electrode 31 may be formed of n-type polysilicon, and the gate field plate 32 may be formed of p-type polysilicon. The p-type polysilicon has a work function different from that of the n-type polysilicon. When the channel is formed immediately below the p-type polysilicon, the threshold voltage at the time of channel formation is higher than that when the channel is formed immediately below the n-type polysilicon. Therefore, when off, the second active area 27 immediately below the gate field plate 32 can be deeply cut off at the gate-source voltage Vgs=−1 V, so that the off-withstand voltage can be improved.

More specifically, the p-type polysilicon gate has a Fermi rank lower than that of the n-type polysilicon gate by 1 V by a band gap. Therefore, when the silicon side band is bent, it is necessary to apply 1 V more than necessary. The cutoff state of the LDMOSFET 10 is Vgs (gate-source voltage)=0 V, which corresponds to Vgs=−1 V in the n-type polysilicon gate in the p-type polysilicon gate, and the gate can be cut off more deeply. As a result, the channel surface conduction component flowing from the source to the drain can be suppressed. From the other side, it can be said that the barrier height of the pn junction between the source and the channel is 1 V higher. Accordingly, the drain cutoff voltage can be increased.

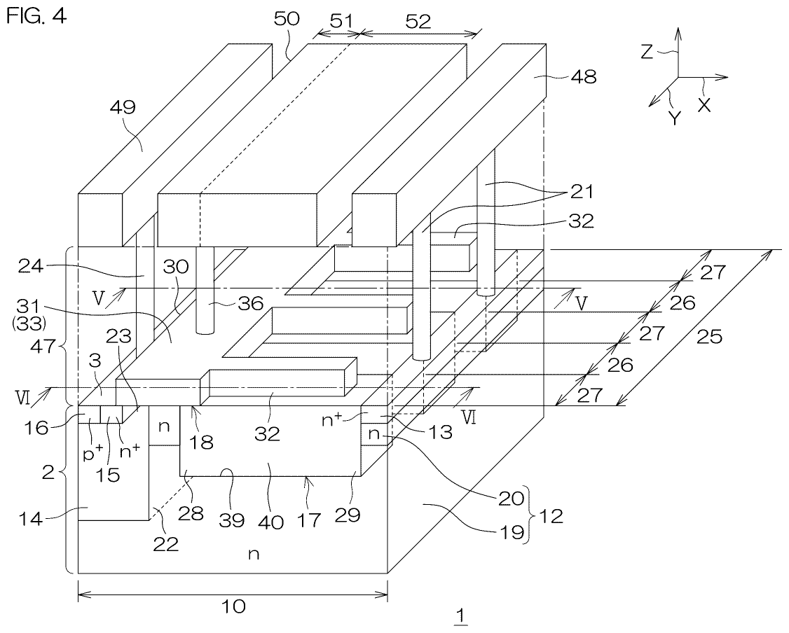

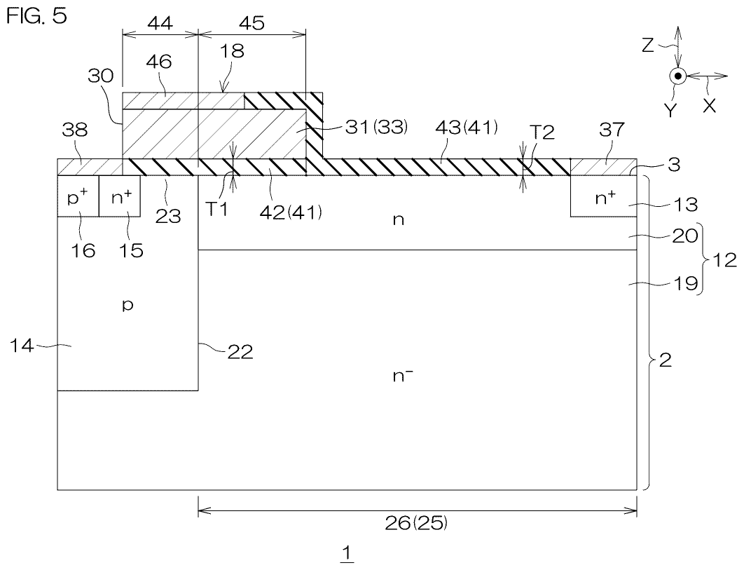

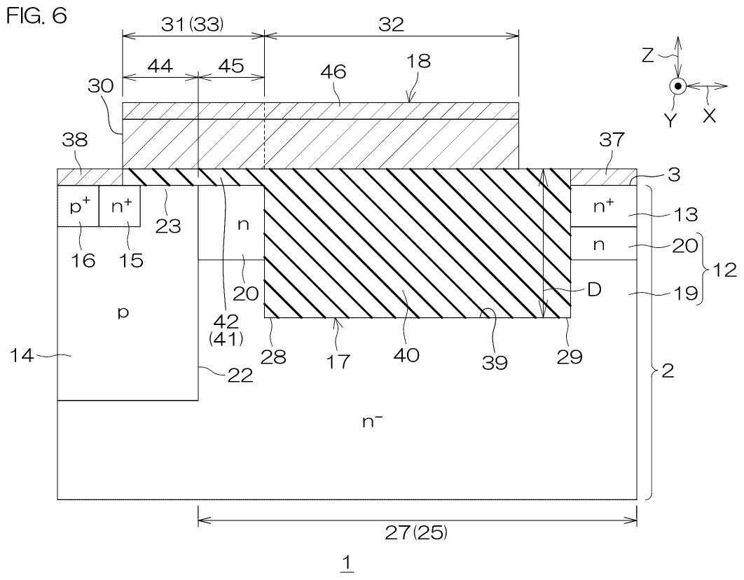

FIG. 4 is a schematic perspective view of the LDMOSFET 10. FIG. 5 is a cross-sectional view taken along line V-V illustrated in FIG. 4. FIG. 6 is a cross-sectional view taken along line VI-VI illustrated in FIG. 4. FIG. 5 illustrates a cross-section of the first active area 26, and FIG. 6 illustrates a cross-section of the second active area 27.

The drift region 12 is formed in a surface layer portion of the semiconductor chip 2. In the drift region 12, the first drift region 19 is formed as a base region, and the second drift region 20 is formed on the first drift region 19. Although not illustrated, a p-type region supporting the drift region 12 may be formed on the second principal surface side of the semiconductor chip 2. The p-type region may be a p-type semiconductor substrate. In this case, the drift region 12 may be an n-type cpitaxial layer. The thickness of the drift region 12 may be 5 μm or more and 20 μm or less.

The drift region 12 is insulated and isolated into a plurality of regions by an element isolation structure (for example, an element isolation well, a deep trench isolation (DTI), a shallow trench isolation (STI), or the like) not illustrated. The element isolation structure partitions the semiconductor chip 2 into a plurality of device regions 9. FIGS. 4 to 6 illustrate the drift region 12 forming the LDMOS region 11 among the plurality of isolated drift regions 12.

The drain region 13 is formed in a surface layer portion of the second drift region 20. The bottom portion of the drain region 13 is located closer to the first principal surface 3 side than the boundary between the first drift region 19 and the second drift region 20 in the third direction Z. A drain silicide 37 is formed on the first principal surface 3 on the drain region 13. The body region 14 penetrates the second drift region 20 and reaches the first drift region 19.

The source region 15 and the body contact region 16 are formed in a surface layer portion of the body region 14. The bottom portions of the source region 15 and the body contact region 16 are located closer to the first principal surface 3 side than the boundary between the first drift region 19 and the body region 14 in the third direction Z. The source silicide 38 is formed on the first principal surface 3 on the source region 15 and the body contact region 16.

Referring to FIG. 6, the insulating isolation structure 17 includes a trench 39 formed in the semiconductor chip 2 and an embedded insulator 40 embedded in the trench 39.

The trench 39 penetrates the second drift region 20 from the first principal surface 3 and reaches the first drift region 19. The trench 39 has a bottom portion at a position deeper than the boundary between the first drift region 19 and the second drift region 20. The embedded insulator 40 is embedded up to the opening end of the trench 39. The embedded insulator 40 is formed of silicon oxide (SiO₂) in this form. The depth D of the trench 39 (the thickness of the insulating isolation structure 17) may be, for example, 0.1 μm or more and 1 μm or less.

As described above, the insulating isolation structure 17 is formed by a so-called shallow trench isolation (STI) structure. As a matter of course, the insulating isolation structure 17 may be formed of a field insulating film such as a LOCOS film. The second active area 27 is formed by the first drift region 19 extending immediately below the insulating isolation structure 17.

On the first principal surface 3, a principal surface insulating film 41 is formed. The principal surface insulating film 41 entirely covers the first principal surface 3. In this form, the principal surface insulating film 41 is formed of silicon oxide (SiO₂), but may be formed of silicon nitride (SiN).

The principal surface insulating film 41 may include a gate insulating film 42 between the gate conductor 18 and the first principal surface 3, and an active covering film 43 covering the first active area 26.

The gate insulating film 42 is sandwiched between the gate conductor 18 and the semiconductor chip 2. The gate insulating film 42 may include a first portion 44 between the gate conductor 18 and the body region 14 (channel region 23) and a second portion 45 between the gate conductor 18 and the drift region 12. The gate insulating film 42 may have a uniform thickness T1 over the entire first portion 44 and the entire second portion 45. The thickness T1 of the gate insulating film 42 is, for example, 2 nm or more and 50 nm or less.

The active covering film 43 is a film that prevents silicidation of the first active area 26 and may be referred to as a silicide block film. The active covering film 43 is thicker than the thickness T1 of the gate insulating film 42, and may have a thickness T2 of, for example, 10 nm or more and 100 nm or less. Referring to FIG. 5, a portion of the active covering film 43 may partially cover a side surface and an upper surface of the gate conductor 18. In the portion covered with the active covering film 43, the gate silicide 46 is formed on the surface of the gate conductor 18.

Referring to FIG. 4, an interlayer film 47 is formed on the first principal surface 3. In FIG. 4, the inside of the interlayer film 47 is illustrated in a see-through manner. The interlayer film 47 covers the gate conductor 18. In this form, the interlayer film 47 is formed of silicon oxide (SiO₂), but may be formed of silicon nitride (SiN).

A drain wiring 48, a source wiring 49, and a gate wiring 50 are formed on the interlayer film 47. The drain wiring 48 is electrically connected to the drain region 13 through the drain contact 21 embedded in the interlayer film 47. In this form, the drain wiring 48 is formed in a band shape extending along the drain region 13 with the interlayer film 47 interposed therebetween, and linearly faces the drain region 13.

The source wiring 49 is electrically connected to the source region 15 and the body contact region 16 through the source contact 24 embedded in the interlayer film 47. In this form, the source wiring 49 is formed in a band shape extending along the source region 15 across the interlayer film 47, and linearly faces the source region 15.

The gate wiring 50 is electrically connected to the gate electrode 31 through a gate contact 36 embedded in the interlayer film 47. Although FIG. 4 illustrates the gate contact 36 connected to the controlling portion 33 of the gate electrode 31, the gate contact 36 may be connected to the contact portion 34 as illustrated in FIG. 2. In this form, the gate wiring 50 is formed in a band shape extending along the gate electrode 31 with the interlayer film 47 interposed therebetween. The gate wiring 50 may integrally include a gate covering portion 51 covering the gate electrode 31 with the interlayer film 47 interposed therebetween, and an active covering portion 52 covering the active area 25 with the interlayer film 47 interposed therebetween.

In this form, the gate covering portion 51 is formed in a band shape extending along the gate electrode 31 with the interlayer film 47 interposed therebetween, and linearly faces the gate electrode 31. In this form, the active covering portion 52 extends across the first active area 26 and the second active area 27 (the insulating isolation structure 17 and the gate field plate 32) along the second direction Y, and faces the first active area 26 and the second active area 27 across the interlayer film 47.

In the semiconductor device 1, for example, the source region 15 and the body contact region 16 are grounded through the source wiring 49, and a positive voltage (drain voltage) is applied to the drain region 13. Then, by controlling the potential of the gate electrode 31, a channel is formed in the channel region 23 in the vicinity of the interface with the gate insulating film 42, and a drain current can flow between the source region 15 and the drain region 13.

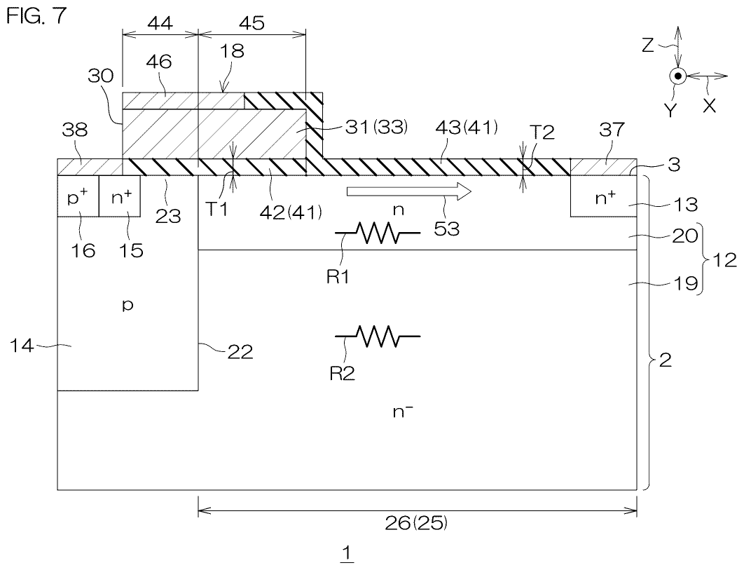

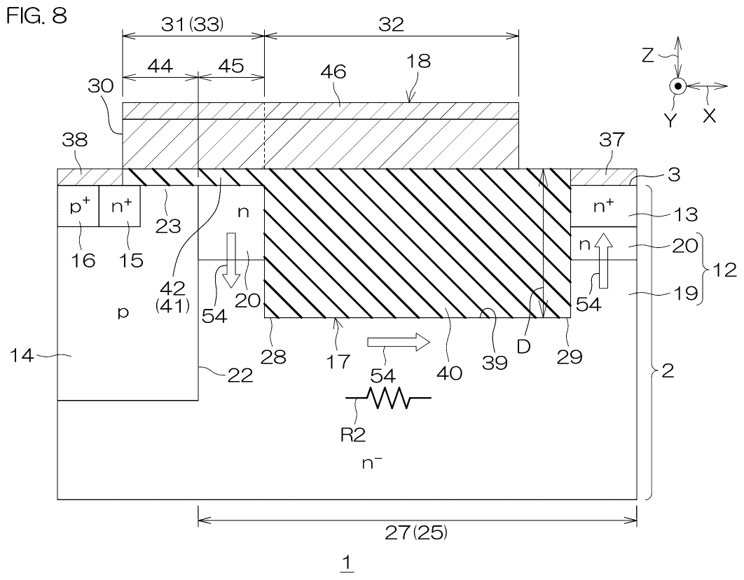

FIGS. 7 and 8 are diagrams illustrating a state in which a flow flows to the first active area 26 and the second active area 27, respectively. FIG. 7 is a cross-sectional view corresponding to FIG. 5, and FIG. 8 is a cross-sectional view corresponding to FIG. 6.

Referring to FIGS. 7 and 8, the first drift region 19 has a first resistance value R1 according to the n-type impurity concentration. The second drift region 20 has a second resistance value R2 in accordance with the n-type impurity concentration thereof. When the first resistance value R1 is compared with the second resistance value R2, the second resistance value R2 is lower than the first resistance value R1. This is because the n-type impurity concentration of the second drift region 20 is lower than the n-type impurity concentration of the first drift region 19.

In addition, since the first active area 26 is a region where the insulating isolation structure 17 is not formed, the current path 53 between the source and the drain is shorter than the current path 54 of the second active area 27. On the other hand, in the second active area 27, since the current flows while bypassing below the insulating isolation structure 17, the current path 54 between the source and the drain is longer than the current path 53 in the first active area 26. Therefore, the current between the source and the drain preferentially flows through the first active area 26 in which the second drift region 20 sandwiched between the plurality of insulating isolation structures 17 is formed. By increasing the n-type impurity concentration of the second drift region 20, a drain current can flow with low on-resistance.

On the other hand, when the LDMOSFET 10 is off, the plurality of insulating isolation structures 17 sandwich the first active area 26 from both sides, and an electric field confinement effect acts, so that a sufficient off-withstand voltage can be obtained even when the second drift region 20 of the first active area 26 has a high concentration.

In the semiconductor device 1, the first active area 26 in which a current preferentially flows at the time of ON and which has a relatively low withstand voltage, and the second active area 27 in which a current hardly flows at the time of ON but which has a high withstand voltage providing a high withstand voltage at the time of OFF are alternately arrayed in parallel. As a result, it is possible to achieve both a low on-resistance and a high off-withstand voltage. Since the on-resistance can be reduced, the loss can be reduced, and the chip area can also be reduced. By reducing the chip area, the number of chips obtained per wafer increases, and the cost can be reduced. In addition, parasitic capacitance and parasitic inductance can be reduced, and signal delay can also be reduced.

In addition, as illustrated in FIG. 4, the gate wiring 50 includes an active covering portion 52 that covers the active area 25 with the interlayer film 47 interposed therebetween. Thereby, a capacitance can be formed between the active area 25 and the gate wiring 50, so that the on-resistance can be reduced and the off-withstand voltage can be improved.

### <Feature Structure of Semiconductor Device 1>

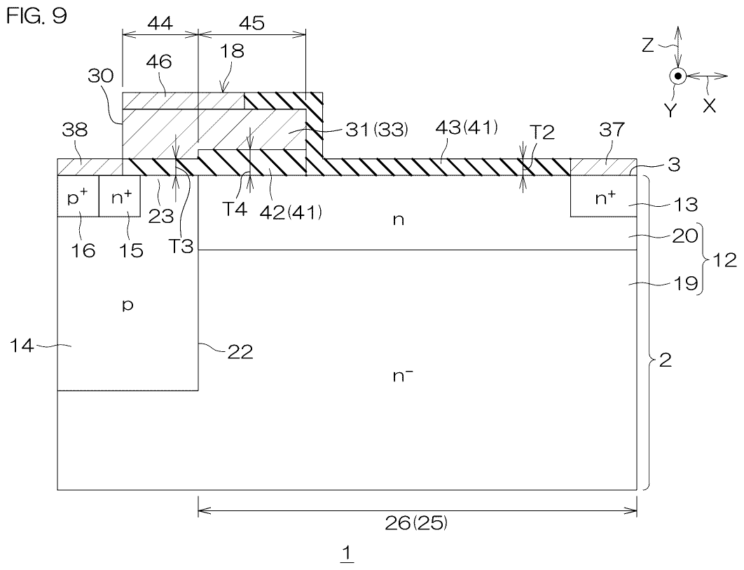

Hereinafter, a characteristic structure that can be introduced into the semiconductor device 1 will be described with reference to FIGS. 9 to 24.

Referring to FIG. 9, in the gate insulating film 42, the thickness T3 of the first portion 44 and the thickness T4 of the second portion 45 may be different from each other. In this form, the thickness T4 of the second portion 45 is larger than the thickness T3 of the first portion 44. The thickness T4 is smaller than the thickness (in this form, the depth D of the trench 39) of the insulating isolation structure 17, and is, for example, 10 nm or more and 100 nm or less. On the other hand, the thickness T3 is, for example, 2 nm or more and 50 nm or less.

By making the thickness T4 of the second portion 45 on the drift region 12 thicker than the thickness T3 of the first portion 44 on the channel region 23 and thinner than the thickness (in this form, the depth D of the trench 39) of the insulating isolation structure 17, it is possible to obtain a sufficient off-withstand voltage while suppressing an increase in on-resistance.

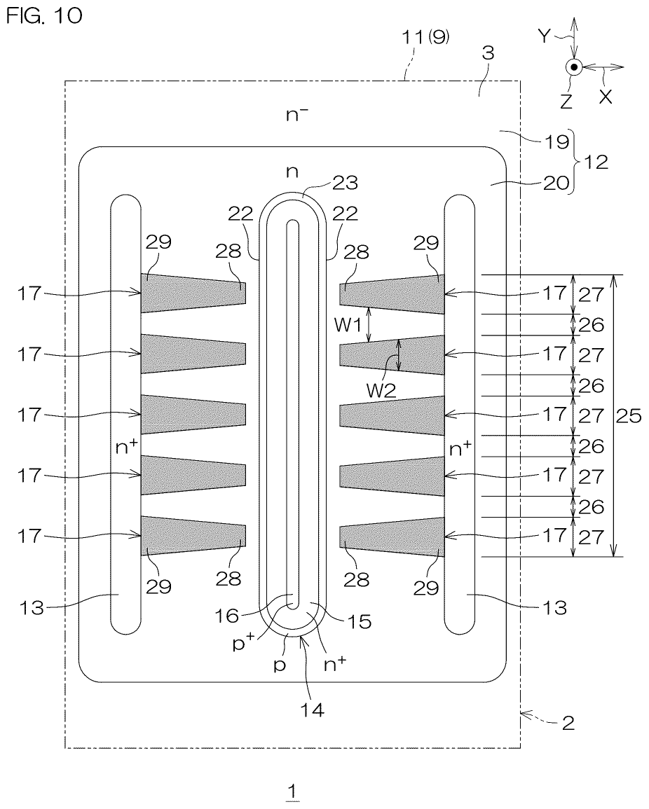

Referring to FIG. 10, the first active area 26 may be formed in a tapered shape in which the width W1 in the second direction Y gradually decreases from the source region 15 toward the drain region 13 in a plan view. In this case, the second active area 27 (insulating isolation structure 17) may be formed in a tapered shape in which the width W2 in the second direction Y gradually decreases from the drain region 13 toward the source region 15 in a plan view. In this form, by widening the width of the second active area 27 on the drain region 13 side where the electric field is relatively less likely to spread as compared with the source region 15 side, electric field concentration can be alleviated, and a sufficient off-withstand voltage can be obtained.

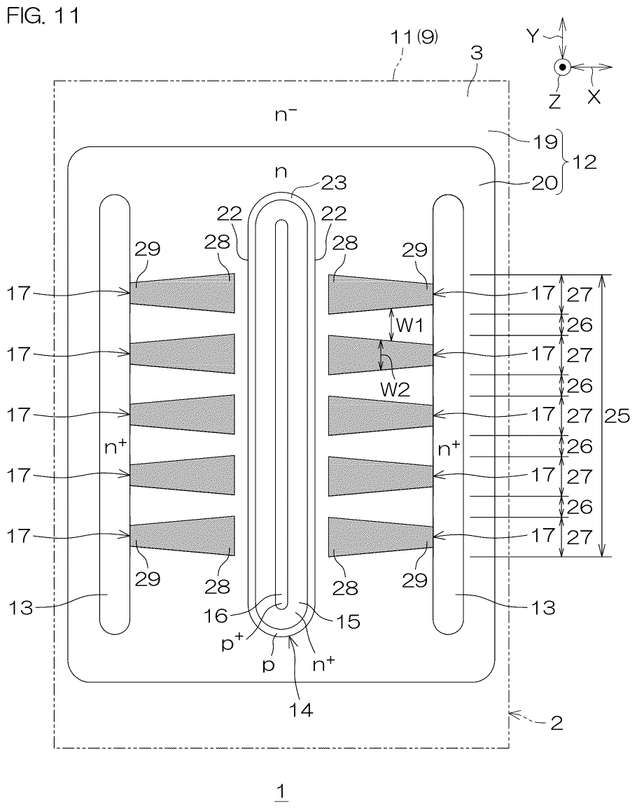

Referring to FIG. 11, the first active area 26 may be formed in a tapered shape in which the width W1 in the second direction Y gradually decreases from the drain region 13 toward the source region 15 in a plan view. In this case, the second active area 27 (insulating isolation structure 17) may be formed in a tapered shape in which the width W2 in the second direction Y gradually decreases from the source region 15 toward the drain region 13 in a plan view. In this form, a sufficient off-withstand voltage can be obtained by narrowing the width of the first active area 26 on the source region 15 side where the electric field tends to be relatively concentrated as compared with the drain region 13 side.

In general, a depletion layer is generated from a pn junction boundary. In this form, the pn junction is a junction between the n-type drain and the p-type body, and its position is located on the source region 15 side with respect to the first active area 26 and the slit-shaped portion of the insulating isolation structure 17. Therefore, when the width W2 of the insulating isolation structure 17, which becomes a factor of determining the off-withstand voltage, is wide on the source region 15 side (in other words, the width W1 of the first active area 26 is narrow on the source region 15 side), electric field concentration can be suppressed. As a result, the off-withstand voltage can be increased.

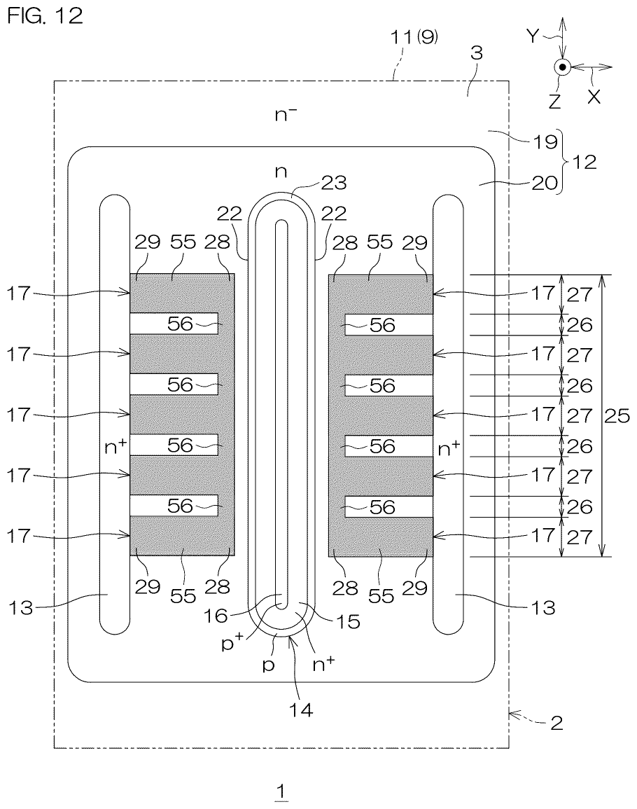

Referring to FIG. 12, the insulating isolation structure 17 may integrally include a first structure 55 and a second structure 56. The first structure 55 extends along the first direction X and sandwiches the first active area 26 in the second direction Y. The second structure 56 extends along the second direction Y and connects the first end portions 28 of the pair of first structures 55 on the source region 15 side. In the adjacent first structures 55, the second end portion 29 on the drain region 13 side is open. Thereby, the first active area 26 is partitioned from three sides by the pair of first structures 55 and the second structure 56 connecting them. In this form, the first active area 26 on the source region 15 side where the electric field is relatively likely to concentrate as compared with the drain region 13 side is closed by the second structure 56, so that a sufficient off-withstand voltage can be obtained.

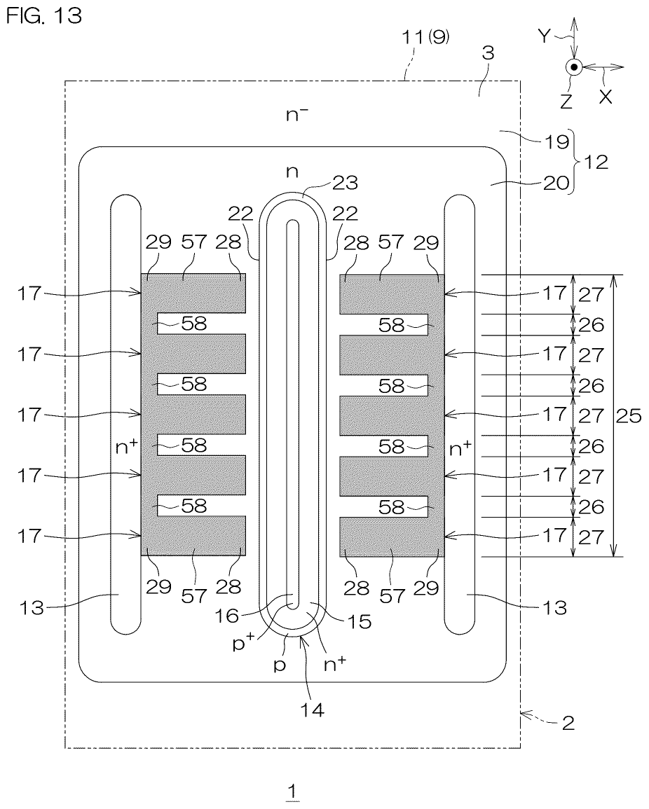

Referring to FIG. 13, the insulating isolation structure 17 may integrally include a first structure 57 and a second structure 58. The first structure 57 extends along the first direction X and sandwiches the first active area 26 in the second direction Y. The second structure 58 extends along the second direction Y and connects the second end portions 29 of the pair of first structures 57 on the drain region 13 side. In the adjacent first structures 57, the first end portion 28 on the source region 15 side is open. Thereby, the first active area 26 is partitioned from three sides by the pair of first structures 57 and the second structure 58 connecting them. In this form, the first active area 26 on the drain region 13 side where the electric field is relatively less likely to spread than on the source region 15 side is closed by the second structure 58, so that a sufficient off-withstand voltage can be obtained.

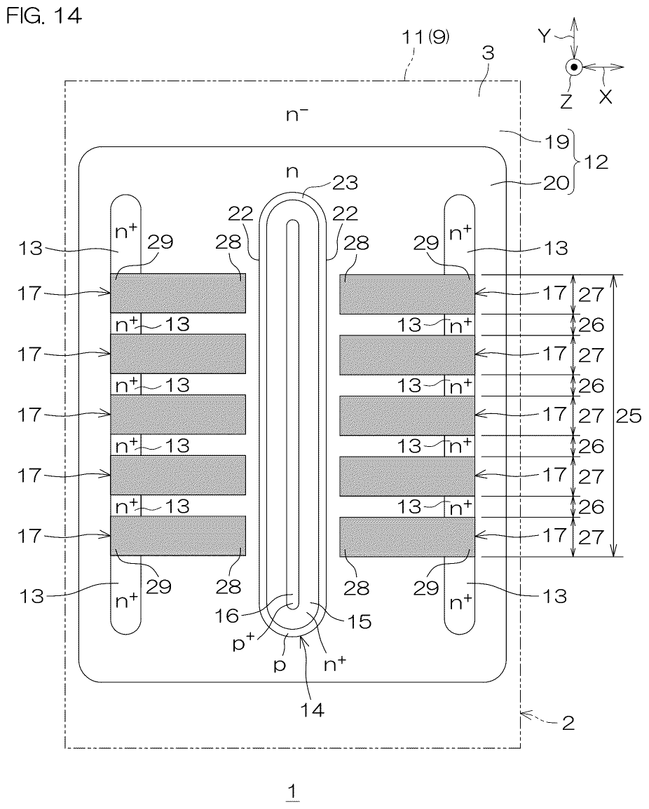

Referring to FIG. 14, the drain region 13 may have both end portions in the second direction Y in contact with the insulating isolation structure 17 and be sandwiched between the adjacent insulating isolation structures 17. In other words, the plurality of insulating isolation structures 17 may cross the drain region 13 (see FIG. 3) having a band-like shape in a plan view in the first direction X to divide the drain region 13 into a plurality of portions. In this form, since a part of the drain region 13 is replaced by the insulating isolation structure 17 and the area of the drain region 13 is reduced, the on-resistance is higher than that in the structure of FIG. 3. However, since the electric field confinement effect from both sides in the second direction Y of the first active area 26 can be improved, the off-withstand voltage can be improved.

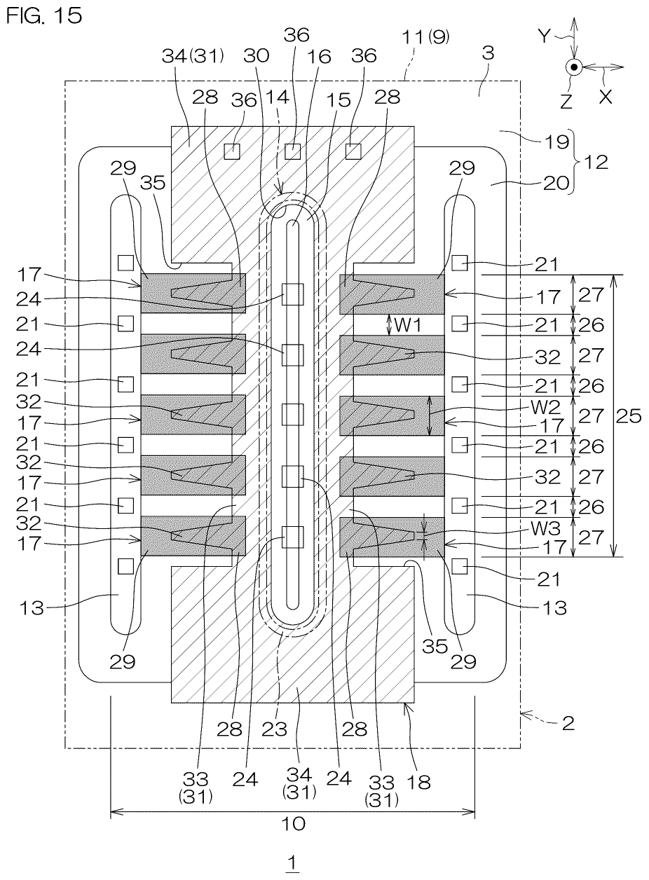

Referring to FIG. 15, the gate field plate 32 may be formed in a tapered shape in which the width W3 in the second direction Y gradually decreases from the source region 15 toward the drain region 13 in a plan view. In this form, a sufficient off-withstand voltage can be obtained by widening the width of the gate field plate 32 on the source region 15 side where the electric field tends to be relatively concentrated as compared with the drain region 13 side.

More specifically, when the LDMOSFET 10 is in a cutoff state, the drain voltage is distributed from the drain to the source. When the gate field plate 32 of 0 V is close to the first active area 26, there is an effect of pushing out the electric field toward the first active area 26 side and the drain region 13 side. Thereby, a large amount of the drain voltage is distributed to the drain side, and the electric field is concentrated. By forming the shape of the gate field plate 32 into a thin wedge shape on the drain side, when the gate field plate is away from the first active area 26 on the drain side, electric field concentration can be alleviated, so that the cutoff withstand voltage can be increased in some cases.

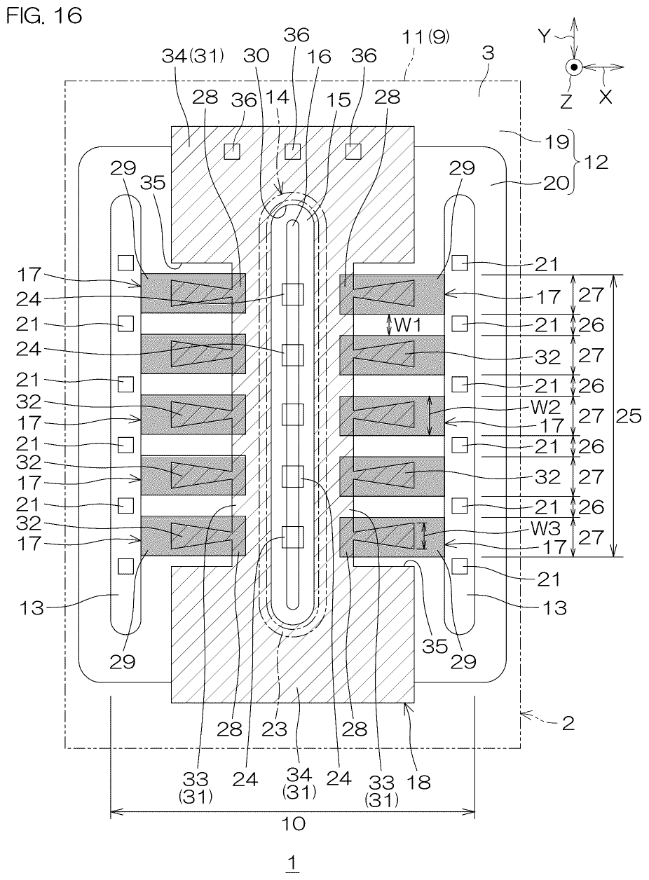

Referring to FIG. 16, the gate field plate 32 may be formed in a tapered shape in which the width W3 in the second direction Y gradually decreases from the drain region 13 toward the source region 15 in a plan view. In this form, a sufficient off-withstand voltage can be obtained by widening the width of the gate field plate 32 on the drain region 13 side where the electric field is relatively less likely to spread as compared with the source region 15 side.

More specifically, for example, in a case where the electric field is concentrated on the source region 15 side due to the drain concentration or other preconditions, when the gate field plate 32 is formed in a thin wedge shape on the source side so as to be away from the first active area 26 on the source side, relaxation of the electric field can be alleviated, and thus the cutoff withstand voltage can be increased in some cases.

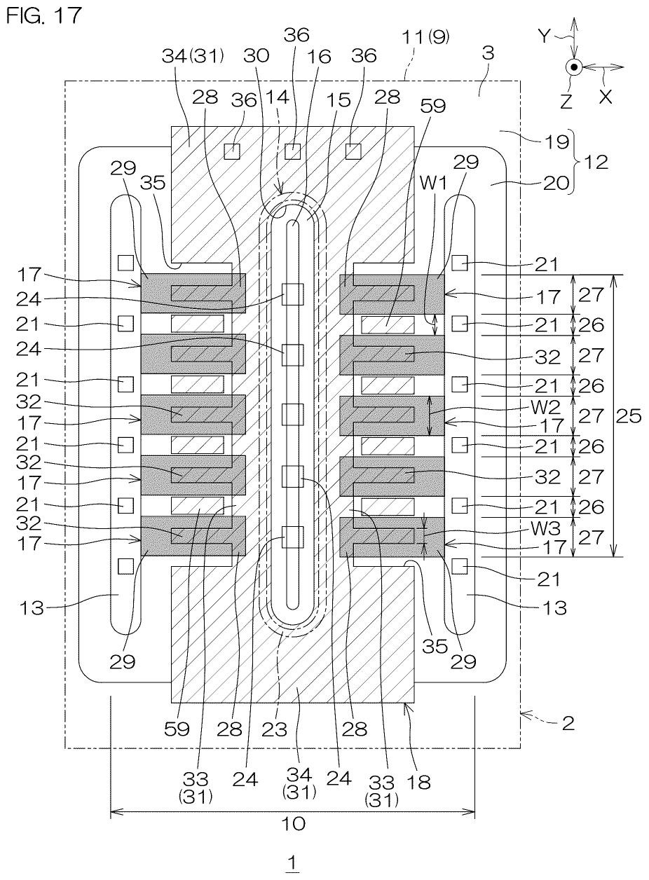

Referring to FIG. 17, the semiconductor device 1 may further include a floating field plate 59 formed on the first active area 26 in an electrically floating state. In this form, each one of a plurality of floating field plates 59 is formed in each first active area 26. Thereby, in the second direction Y, the gate field plates 32 and the floating field plates 59 are alternately arrayed at intervals.

Each floating field plate 59 is formed in a band shape extending in the first direction X. More specifically, the insulating isolation structure is formed in a rectangular shape having a long side along the first direction X and a short side along the second direction Y. Thereby, the width of each floating field plate 59 in the second direction Y is constant. As illustrated in FIG. 17, each floating field plate 59 may be formed only inside the first active area 26 with respect to the boundary between the first active area 26 and the insulating isolation structure 17, or may cross the boundary between the first active area 26 and the insulating isolation structure 17 to partially cover the insulating isolation structure 17.

In this form, since the floating field plate 59 is located on the first active area 26, the electric field concentration in the surface layer portion of the first active area 26 can be alleviated. Accordingly, the off-withstand voltage can be improved.

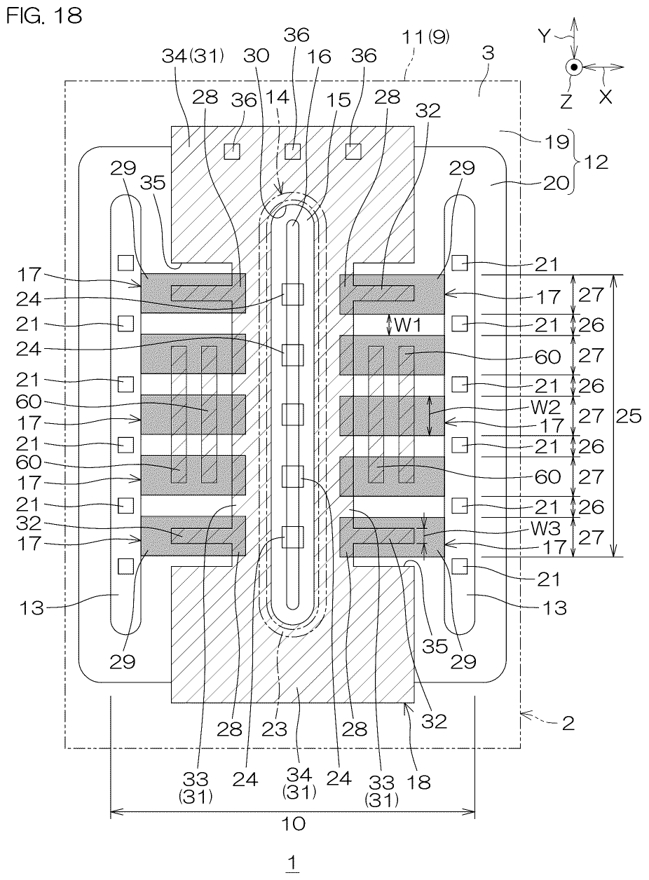

Referring to FIG. 18, the semiconductor device 1 may further include a floating field plate 60 that extends across the first active area 26 and the insulating isolation structure 17 (second active area 27) in the second direction Y and is in an electrically floating state. In this form, the plurality of floating field plates 60 are arrayed at intervals in the first direction X.

Each floating field plate 60 is formed in a band shape extending in the second direction Y. More specifically, the floating field plate is formed in a rectangular shape having a long side along the second direction Y and a short side along the first direction X. Thereby, the width of each floating field plate 60 in the first direction X is constant. Each floating field plate 60 may continuously traverse the plurality of first active areas 26 and the plurality of insulating isolation structures 17, as illustrated in FIG. 18, or may only traverse a boundary between one first active area 26 and one insulating isolation structure 17.

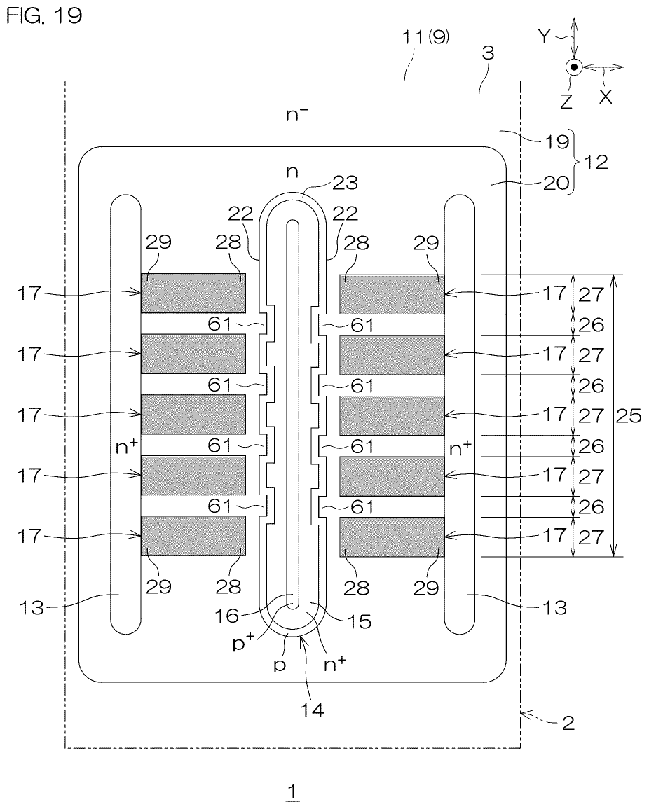

Referring to FIG. 19, the drift region 12 (in this form, the second drift region 20) has a protrusion portion 61 selectively protruding from the first active area 26 toward the body region 14 in the first direction X. In this form, the plurality of protrusion portions 61 are arrayed at intervals in the second direction Y, and one protrusion portion 61 protrudes from each first active area 26.

Thereby, the boundary 22 between the body region 14 and the second drift region 20 is formed in a zigzag shape that protrudes toward the source region 15 side in a section adjacent to the first active area 26 and protrudes toward the drain region 13 side in a section adjacent to the insulating isolation structure 17. As illustrated in FIG. 19, the zigzag of the boundary 22 may be formed in a pulse waveform shape or a sine curve shape.

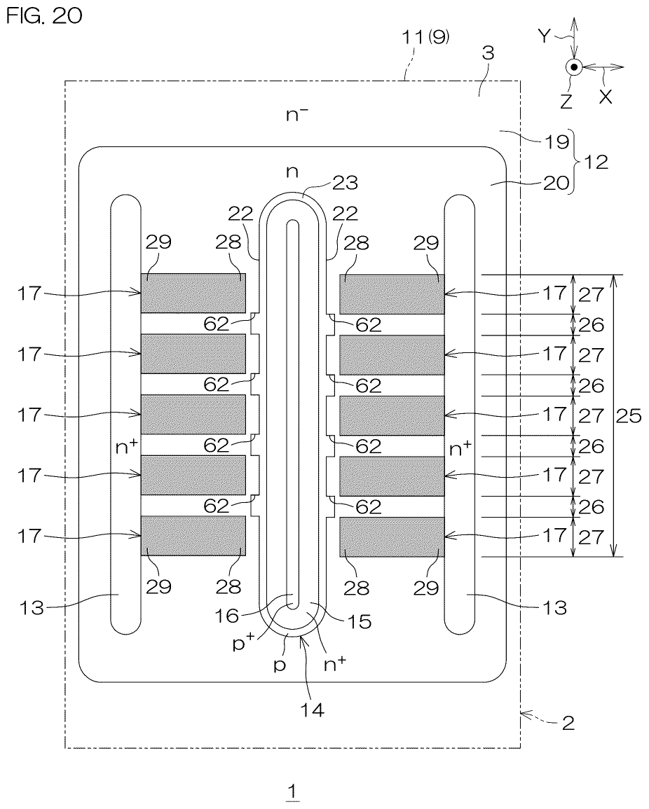

Referring to FIG. 20, the drift region 12 (in this form, the second drift region 20) has a recess portion 62 selectively recessed from the body region 14 toward the first active area 26 in the first direction X. In this form, the plurality of recess portion 62 are arrayed at intervals in the second direction Y, and one recess portion 62 is provided toward each first active area 26.

Thereby, the boundary 22 between the body region 14 and the second drift region 20 is formed in a zigzag shape that is concave toward the drain region 13 side in a section adjacent to the first active area 26 and convex toward the source region 15 side in a section adjacent to the insulating isolation structure 17. As illustrated in FIG. 20, the zigzag of the boundary 22 may be formed in a pulse waveform shape or a sine curve shape.

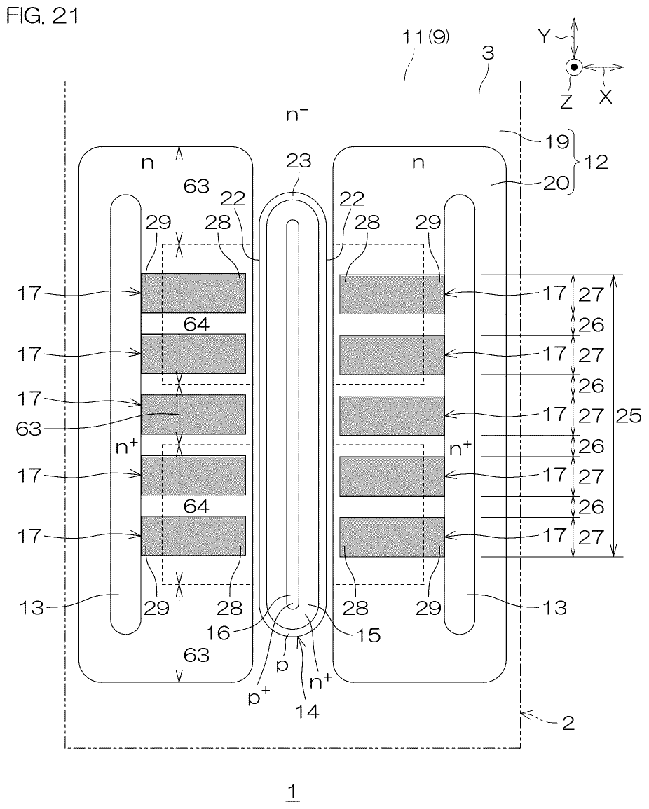

Referring to FIG. 21, the second drift region 20 may include a plurality of first diffusion regions 63 and a plurality of second diffusion regions 64 alternately arrayed in a stripe shape in the second direction Y. The plurality of first diffusion regions 63 may have an n-type impurity concentration higher than that of the plurality of second diffusion regions 64. In this form, the plurality of first diffusion regions 63 and the plurality of second diffusion regions 64 are alternately arrayed in the second direction Y.

For example, n-type impurities are selectively implanted into a region of the first drift region 19 where the first diffusion region 63 is to be formed, and then annealing processing is performed. Thereby, impurities are diffused from the first diffusion region 63 in the lateral direction along the first principal surface 3. As a result, the second diffusion region 64 having an impurity concentration lower than that of the first diffusion region 63 and an impurity concentration higher than that of the first drift region 19 can be formed.

In this form, since the mask of the diffusion layer of the existing striped pattern can be substituted for the impurity implantation into the wafer, a dedicated mask for the second drift region 20 is unnecessary. Thereby, the manufacturing cost can be reduced. In addition, since the diffusion range of the impurity concentration can be adjusted by adjusting the width of the striped pattern, the impurity concentration of the second diffusion region 64 can also be adjusted.

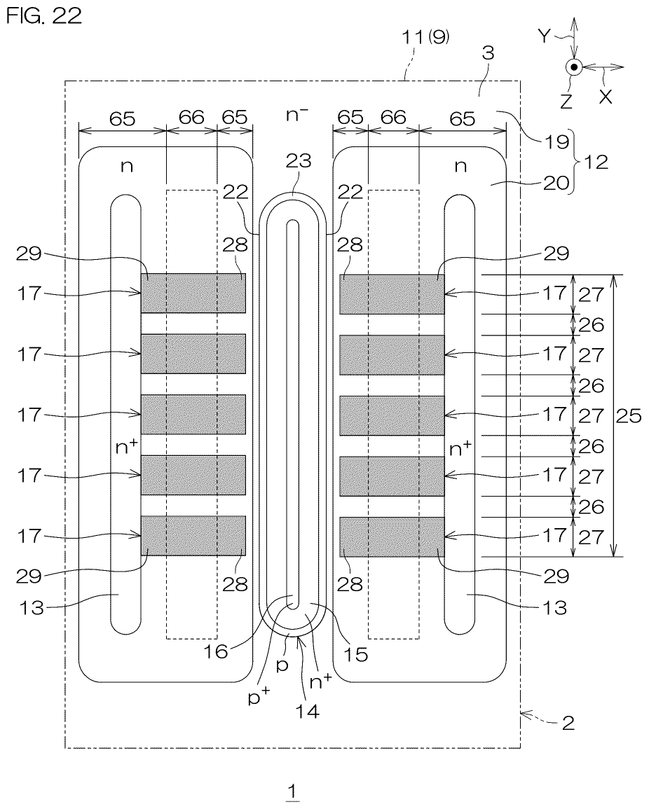

Referring to FIG. 22, the second drift region 20 may include a plurality of first diffusion regions 65 and a plurality of second diffusion regions 66 alternately arrayed in a stripe shape in the first direction X. The plurality of first diffusion regions 65 may have an n-type impurity concentration higher than that of the plurality of second diffusion regions 66. In this form, the plurality of first diffusion regions 65 and the plurality of second diffusion regions 66 are alternately arrayed in the first direction Y.

For example, n-type impurities are selectively implanted into a region of the first drift region 19 where the first diffusion region 65 is to be formed, and then annealing processing is performed. Thereby, impurities are diffused from the first diffusion region 65 in the lateral direction along the first principal surface 3. As a result, the second diffusion region 66 having an impurity concentration lower than that of the first diffusion region 65 and an impurity concentration higher than that of the first drift region 19 can be formed.

In this form, since the mask of the diffusion layer of the existing striped pattern can be substituted for the impurity implantation into the wafer, a dedicated mask for the second drift region 20 is unnecessary. Thereby, the manufacturing cost can be reduced. In addition, since the diffusion range of the impurity concentration can be adjusted by adjusting the width of the stripe shape, the impurity concentration of the second diffusion region 66 can also be adjusted.

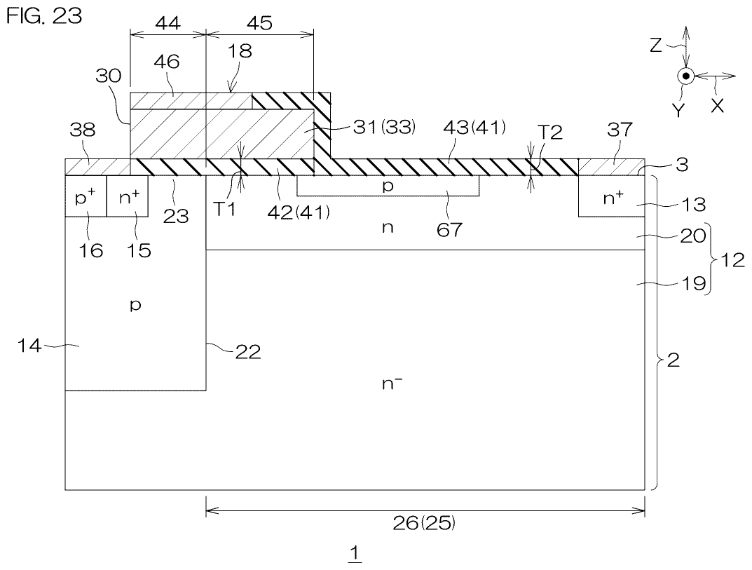

Referring to FIG. 23, the semiconductor device 1 may further include a p-type top diffusion region 67 selectively formed in a surface layer portion of the second drift region 20 in the first active area 26. The top diffusion region 67 is separated from the bottom portion and the side portion (boundary 22 with the body region 14) of the second drift region 20 and is formed in a floating state in the second drift region 20. The top diffusion region 67 is covered with the active covering film 43 and physically isolated from any of the drain contact 21, the source contact 24, and the gate contact 36.

In this form, the p-type top diffusion region 67 is formed in the second drift region 20. Thereby, the depletion layer can be expanded from the pn junction portion between the top diffusion region 67 (p-type) and the second drift region 20 (n-type). Thereby, electric field relaxation in the second drift region 20 having an n-type impurity concentration higher than that of the first drift region 19 can be promoted, so that the off-withstand voltage can be improved. In addition, in forming the top diffusion region 67, manufacturing cost can be reduced by substituting a mask of a diffusion layer of an existing pattern.

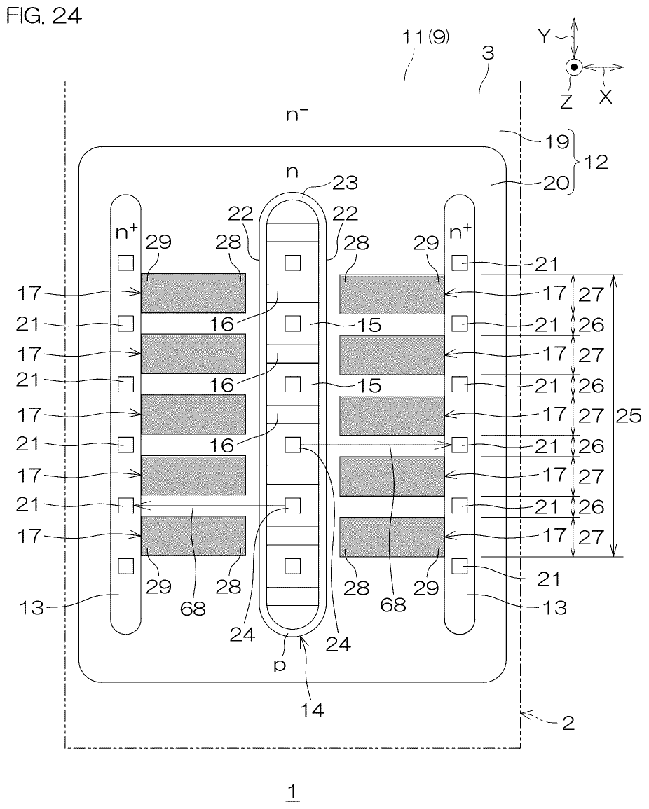

Referring to FIG. 24, in this form, in the body region 14, the plurality of source regions 15 and the plurality of body contact regions 16 are alternately arrayed in the second direction Y. More specifically, in the body region 14, the source region 15 is formed in a section adjacent to the first active area 26, and the body contact region 16 is formed in a section adjacent to the insulating isolation structure 17. In addition, the plurality of source contacts 24 are connected to each of the plurality of source regions 15. Therefore, each source contact 24 is located at a position adjacent to the first active area 26 in the first direction X.

In this form, both the source region 15 and the source contact 24 are adjacent to the first active area 26 in the first direction X. Thereby, since the source contact 24, the first active area 26, and the drain contact 21 are linearly located in the first direction X, a current can flow through the short current path 68 between the source and the drain.

Although preferred embodiments of the present disclosure have been described above, the present disclosure can be implemented in yet other preferred embodiments.

For example, in the above-described preferred embodiment, an example in which the first conductivity type is n-type and the second conductivity type is p-type has been described, but the first conductivity type may be p-type and the second conductivity type may be n-type. A specific configuration in this case is obtained by replacing the n-type region with the p-type region and replacing the p-type region with the n-type region in the above description and the accompanying drawings.

Preferred embodiments of the present disclosure are illustrative in all respects and should not be construed in a limiting manner, and are intended to include modifications in all respects.

The following appended features can be extracted from the descriptions in this description and the drawings.

### [Appendix 1-1]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the gate insulating film (42) includes a first portion (44) formed on the channel region (23) and a second portion (45) integrally extending from the first portion (44) toward the drain region (13), formed on the drift region (12), and having a second thickness (T4) larger than a first thickness (T3) of the first portion (44).

### [Appendix 1-2]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the first active area (26) is formed in a tapered shape in which a width (W1) in the second direction (Y) gradually decreases from the source region (15) toward the drain region (13) in a plan view.

### [Appendix 1-3]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the first active area (26) is formed in a tapered shape in which a width (W1) in the second direction (Y) gradually decreases from the drain region (13) toward the source region (15) in a plan view.

### [Appendix 1-4]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the insulating isolation structure (17) integrally includes a pair of first structures (55) extending in the first direction (X) and sandwiching the first active area (26) in the second direction (Y) and a second structure (56) extending in the second direction (Y) and connecting end portions (28) of the pair of first structures (55) on the source region (15) side, and partitions the first active area (26) from three sides.

### [Appendix 1-5]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the insulating isolation structure (17) integrally includes a pair of first structures (57) extending in the first direction (X) and sandwiching the first active area (26) in the second direction (Y) and a second structure (58) extending in the second direction (Y) and connecting end portions (29) of the pair of first structures (57) on the drain region (13) side, and partitions the first active area (26) from three sides.

### [Appendix 1-6]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the drain region (13) has both end portions in the second direction (Y) in contact with the insulating isolation structure (17) and is sandwiched between the adjacent insulating isolation structures (17).

### [Appendix 1-7]

The semiconductor device (1) according to any one of Appendices 1-1 to 1-6,
wherein the insulating isolation structure (17) includes a trench (39) formed in the semiconductor chip (2) and an embedded insulator (40) embedded in the trench (39).

### [Appendix 1-8]

The semiconductor device (1) according to Appendix 1-7,
wherein the drift region (12) includes a first drift region (19) having a first impurity concentration and a second drift region (20) formed on the first drift region (19) and having a second impurity concentration higher than the first impurity concentration, and
the trench (39) has a bottom portion at a position deeper than a boundary between the first drift region (19) and the second drift region (20).

### [Appendix 1-9]

The semiconductor device (1) according to any one of Appendices 1-1 to 1-8,
wherein a plurality of the first active areas (26) and a plurality of the insulating isolation structures (17) are alternately arrayed in the second direction (Y).

### [Appendix 1-10]

The semiconductor device (1) according to any one of Appendices 1-1 to 1-9, further including:
a second active area (27) formed immediately below the insulating isolation structure (17) in a thickness direction of the semiconductor chip (2),
wherein the drift region (12) has a higher impurity concentration in the first active area (26) than in the second active area (27).

### [Appendix 2-1]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X),
a gate field plate (32) extending from the gate electrode (31) to a region on the insulating isolation structure (17), and
a gate wiring (50) electrically connected to the gate electrode (31),
wherein the gate wiring (50) is separated from the first active area in a thickness direction of the semiconductor chip (2) and includes a covering portion (52) covering the first active area (26).

### [Appendix 2-2]

The semiconductor device (1) according to Appendix 2-2, further including:
an interlayer film (47) covering the gate electrode (31) and the gate field plate (32),
wherein the covering portion (52) of the gate wiring (50) is formed on the interlayer film (47).

### [Appendix 2-3]

The semiconductor device (1) according to Appendix 2-2,
wherein a plurality of the first active areas (26) and a plurality of the insulating isolation structures (17) are alternately arrayed in the second direction (Y), and
the covering portion (52) of the gate wiring (50) extends across the plurality of first active areas (26) and the plurality of insulating isolation structures (17) along the second direction (Y).

### [Appendix 2-4]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the gate electrode (31) and the gate field plate (32) are formed of n-type polysilicon.

### [Appendix 2-5]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the gate electrode (31) is formed of n-type polysilicon, and the gate field plate (32) is formed of p-type polysilicon.

### [Appendix 2-6]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and a gate field plate (32) extending from the gate electrode (31) to a region on the insulating isolation structure (17),
wherein the gate field plate (32) is formed in a tapered shape in which a width (W3) in the second direction (Y) gradually decreases from the source region (15) toward the drain region (13) in a plan view.

### [Appendix 2-7]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the gate field plate (32) is formed in a tapered shape in which a width (W3) in the second direction (Y) gradually decreases from the drain region (13) toward the source region (15) in a plan view.

### [Appendix 2-8]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X),
a gate field plate (32) extending from the gate electrode (31) to a region on the insulating isolation structure (17), and
a floating field plate (59) formed on the first active area (26) in an electrically floating state.

### [Appendix 2-9]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a floating field plate (60) that extends across the first active area (26) and the insulating isolation structure (17) in the second direction (Y) and is in an electrically floating state.

### [Appendix 2-10]

The semiconductor device (1) according to any one of Appendices 2-1 to 2-9,
wherein the insulating isolation structure (17) includes a trench (39) formed in the semiconductor chip (2) and an embedded insulator (40) embedded in the trench (39).

### [Appendix 2-11]

The semiconductor device (1) according to Appendix 2-10,
wherein the drift region (12) includes a first drift region (19) having a first impurity concentration and a second drift region (20) formed on the first drift region (19) and having a second impurity concentration higher than the first impurity concentration, and
the trench (39) has a bottom portion at a position deeper than a boundary between the first drift region (19) and the second drift region (20).

### [Appendix 2-12]

The semiconductor device (1) according to any one of Appendices 2-1 to 2-9, further including:
a second active area (27) formed immediately below the insulating isolation structure (17) in a thickness direction of the semiconductor chip (2),
wherein the drift region (12) has a higher impurity concentration in the first active area (26) than in the second active area (27).

### [Appendix 3-1]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the drift region (12) includes a protrusion portion (61) selectively protruding from the first active area (26) toward the body region (14) in the first direction (X).

### [Appendix 3-2]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the drift region (12) has a recess portion (62) selectively recessed from the body region (14) toward the first active area (26) in the first direction (X).

### [Appendix 3-3]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the drift region (12) includes a first drift region (19) having a first impurity concentration and a second drift region (20) formed on the first drift region (19) and having a second impurity concentration higher than the first impurity concentration,
the second drift region (20) includes a plurality of first diffusion regions (63) and a plurality of second diffusion regions (64) alternately arrayed in a stripe shape in the second direction (Y), and
the plurality of first diffusion regions (63) have a first conductivity type impurity concentration higher than that of the plurality of second diffusion regions (64).

### [Appendix 3-4]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the drift region (12) includes a first drift region (19) having a first impurity concentration and a second drift region (20) formed on the first drift region (19) and having a second impurity concentration higher than the first impurity concentration,
the second drift region (20) includes a plurality of first diffusion regions (65) and a plurality of second diffusion regions (66) alternately arrayed in a stripe shape in the first direction (X), and
the plurality of first diffusion regions (65) have a first conductivity type impurity concentration higher than that of the plurality of second diffusion regions (66).

### [Appendix 3-5]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein the drift region (12) includes a first drift region (19) having a first impurity concentration and a second drift region (20) formed on the first drift region (19) and having a second impurity concentration higher than the first impurity concentration, and
the semiconductor device further includes: a top diffusion region (67) of a second conductivity type selectively formed in a surface layer portion of the second drift region (20) in the first active area (26).

### [Appendix 3-6]

The semiconductor device (1) according to Appendix 3-1 or 3-2,
wherein the insulating isolation structure (17) includes a trench (39) formed in the semiconductor chip (2) and an embedded insulator (40) embedded in the trench (39).

### [Appendix 3-7]

The semiconductor device (1) according to Appendix 3-7,
wherein the drift region (12) includes a first drift region (19) having a first impurity concentration and a second drift region (20) formed on the first drift region (19) and having a second impurity concentration higher than the first impurity concentration, and
the trench (39) has a bottom portion at a position deeper than a boundary between the first drift region (19) and the second drift region (20).

### [Appendix 3-8]

The semiconductor device (1) according to any one of Appendices 3-1 to 3-5,
wherein a plurality of the first active areas (26) and a plurality of the insulating isolation structures (17) are alternately arrayed in the second direction (Y).

### [Appendix 3-9]

The semiconductor device (1) according to Appendix 3-1 or 3-2, further including:
a second active area (27) formed immediately below the insulating isolation structure (17) in a thickness direction of the semiconductor chip (2),
wherein the drift region (12) has a higher impurity concentration in the first active area (26) than in the second active area (27).

### [Appendix 4-1]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a body contact region (16) of a second conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein a plurality of the source regions (15) and a plurality of the body contact regions (16) are alternately arrayed in the second direction (Y), and
each of the source regions (15) is adjacent to the first active area (26) in the first direction (X).

### [Appendix 4-2]

A semiconductor device (1) including:
a semiconductor chip (2) having a principal surface (3),
a drift region (12) of a first conductivity type formed in a surface layer portion of the principal surface (3) of the semiconductor chip (2),
a drain region (13) of a first conductivity type formed in a surface layer portion of the drift region (12),
a body region (14) of a second conductivity type formed in a surface layer portion of the drift region (12) and separated from the drain region (13) in a first direction (X),
a source region (15) of a first conductivity type formed in a surface layer portion of the body region (14),
a body contact region (16) of a second conductivity type formed in a surface layer portion of the body region (14),
a gate insulating film (42) formed on the principal surface (3) of the semiconductor chip (2),
a gate electrode (31) formed on the gate insulating film (42) and facing a channel region (23) formed in the body region (14),
a plurality of insulating isolation structures (17) embedded in a surface layer portion of the principal surface (3) of the semiconductor chip (2) along the first direction (X) between the body region (14) and the drain region (13),
a first active area (26) sandwiched between the adjacent insulating isolation structures (17) in a second direction (Y) intersecting the first direction (X), and
a gate field plate (32) extending from the gate electrode (31) to a region on the insulating isolation structure (17),
wherein a plurality of the source regions (15) and a plurality of the body contact regions (16) are alternately arrayed in the second direction (Y),
the semiconductor device further includes: a plurality of source contacts (24) arrayed along the second direction (Y) and connected to the source region (15) and the body contact region (16), and
the plurality of source contacts (24) are adjacent to the first active area (26) in the first direction (X).

### [Appendix 4-3]

The semiconductor device (1) according to Appendix 4-1 or 4-2,
wherein the insulating isolation structure (17) includes a trench (39) formed in the semiconductor chip (2) and an embedded insulator (40) embedded in the trench (39).

### [Appendix 4-4]

The semiconductor device (1) according to Appendix 4-3,
wherein the drift region (12) includes a first drift region (19) having a first impurity concentration and a second drift region (20) formed on the first drift region (19) and having a second impurity concentration higher than the first impurity concentration, and
the trench (39) has a bottom portion at a position deeper than a boundary between the first drift region (19) and the second drift region (20).

### [Appendix 4-5]

The semiconductor device (1) according to Appendix 4-1 or 4-2,
wherein a plurality of the first active areas (26) and a plurality of the insulating isolation structures (17) are alternately arrayed in the second direction (Y).

### [Appendix 4-6]

The semiconductor device (1) according to Appendix 4-1 or 4-2, further including:
a second active area (27) formed immediately below the insulating isolation structure (17) in a thickness direction of the semiconductor chip (2),
wherein the drift region (12) has a higher impurity concentration in the first active area (26) than in the second active area (27).

1. A semiconductor device comprising:
a semiconductor chip having a principal surface,
a drift region of a first conductivity type formed in a surface layer portion of the principal surface of the semiconductor chip,
a drain region of a first conductivity type formed in a surface layer portion of the drift region,
a body region of a second conductivity type formed in a surface layer portion of the drift region and separated from the drain region in a first direction,
a source region of a first conductivity type formed in a surface layer portion of the body region,
a gate insulating film formed on the principal surface of the semiconductor chip,
a gate electrode formed on the gate insulating film and facing a channel region formed in the body region,
a plurality of insulating isolation structures embedded in a surface layer portion of the principal surface of the semiconductor chip along the first direction between the body region and the drain region,
a first active area sandwiched between the adjacent insulating isolation structures in a second direction intersecting the first direction, and
a gate field plate extending from the gate electrode to a region on the insulating isolation structure,
the gate insulating film includes a first portion formed on the channel region and a second portion integrally extending from the first portion toward the drain region, formed on the drift region, and having a second thickness larger than a first thickness of the first portion.

2. The semiconductor device according to claim 1, wherein the insulating isolation structure integrally includes a pair of first structures extending along the first direction and sandwiching the first active area in the second direction and a second structure extending along the second direction and connecting end portions of the pair of first structures on the source region side, and partitions the first active area from three sides.

3. The semiconductor device according to claim 1, wherein the insulating isolation structure integrally includes a pair of first structures extending along the first direction and sandwiching the first active area in the second direction and a second structure extending along the second direction and connecting end portions of the pair of first structures on the drain region side, and partitions the first active area from three sides.

4. The semiconductor device according to claim 1, wherein both end portions of the drain region in the second direction are in contact with the insulating isolation structure, and the drain region is sandwiched between the adjacent insulating isolation structures.

5. A semiconductor device comprising:
a semiconductor chip having a principal surface,
a drift region of a first conductivity type formed in a surface layer portion of the principal surface of the semiconductor chip,
a drain region of a first conductivity type formed in a surface layer portion of the drift region,
a body region of a second conductivity type formed in a surface layer portion of the drift region and separated from the drain region in a first direction,
a source region of a first conductivity type formed in a surface layer portion of the body region,
a gate insulating film formed on the principal surface of the semiconductor chip,
a gate electrode formed on the gate insulating film and facing a channel region formed in the body region,
a plurality of insulating isolation structures embedded in a surface layer portion of the principal surface of the semiconductor chip along the first direction between the body region and the drain region, and
a first active area sandwiched between the adjacent insulating isolation structures in a second direction intersecting the first direction, and
a gate field plate extending from the gate electrode to a region on the insulating isolation structure,
wherein the first active area is formed in a tapered shape in which a width in the second direction gradually decreases from the source region toward the drain region in a plan view.

6. The semiconductor device according to claim 5, wherein the insulating isolation structure integrally includes a pair of first structures extending along the first direction and sandwiching the first active area in the second direction and a second structure extending along the second direction and connecting end portions of the pair of first structures on the source region side, and partitions the first active area from three sides.

7. The semiconductor device according to claim 5, wherein the insulating isolation structure integrally includes a pair of first structures extending along the first direction and sandwiching the first active area in the second direction and a second structure extending along the second direction and connecting end portions of the pair of first structures on the drain region side, and partitions the first active area from three sides.

8. The semiconductor device according to claim 5, wherein both end portions of the drain region in the second direction are in contact with the insulating isolation structure, and the drain region is sandwiched between the adjacent insulating isolation structures.

9. A semiconductor device comprising:
a semiconductor chip having a principal surface,
a drift region of a first conductivity type formed in a surface layer portion of the principal surface of the semiconductor chip,
a drain region of a first conductivity type formed in a surface layer portion of the drift region,
a body region of a second conductivity type formed in a surface layer portion of the drift region and separated from the drain region in a first direction,
a source region of a first conductivity type formed in a surface layer portion of the body region,
a gate insulating film formed on the principal surface of the semiconductor chip,
a gate electrode formed on the gate insulating film and facing a channel region formed in the body region,
a plurality of insulating isolation structures embedded in a surface layer portion of the principal surface of the semiconductor chip along the first direction between the body region and the drain region,
a first active area sandwiched between the adjacent insulating isolation structures in a second direction intersecting the first direction, and
a gate field plate extending from the gate electrode to a region on the insulating isolation structure,
wherein the first active area is formed in a tapered shape in which a width in the second direction gradually decreases from the drain region toward the source region in a plan view.

10. The semiconductor device according to claim 9, wherein the insulating isolation structure integrally includes a pair of first structures extending along the first direction and sandwiching the first active area in the second direction and a second structure extending along the second direction and connecting end portions of the pair of first structures on the source region side, and partitions the first active area from three sides.

11. The semiconductor device according to claim 9, wherein the insulating isolation structure integrally includes a pair of first structures extending along the first direction and sandwiching the first active area in the second direction and a second structure extending along the second direction and connecting end portions of the pair of first structures on the drain region side, and partitions the first active area from three sides.

12. The semiconductor device according to claim 9, wherein both end portions of the drain region in the second direction are in contact with the insulating isolation structure, and the drain region is sandwiched between the adjacent insulating isolation structures.

13. The semiconductor device according to claim 1,
wherein the insulating isolation structure includes a trench formed in the semiconductor chip and an embedded insulator embedded in the trench.

14. The semiconductor device according to claim 13,
wherein the drift region includes a first drift region having a first impurity concentration and a second drift region formed on the first drift region and having a second impurity concentration higher than the first impurity concentration, and
the trench has a bottom portion at a position deeper than a boundary between the first drift region and the second drift region.

15. The semiconductor device according to claim 1, wherein a plurality of the first active areas and a plurality of the insulating isolation structures are alternately arrayed in the second direction.

16. The semiconductor device according to claim 1, further comprising:
a second active area formed immediately below the insulating isolation structure in a thickness direction of the semiconductor chip,
wherein the drift region has a higher impurity concentration in the first active area than in the second active area.

17. The semiconductor device according to claim 5,
wherein the insulating isolation structure includes a trench formed in the semiconductor chip and an embedded insulator embedded in the trench.

18. The semiconductor device according to claim 17,
wherein the drift region includes a first drift region having a first impurity concentration and a second drift region formed on the first drift region and having a second impurity concentration higher than the first impurity concentration, and
the trench has a bottom portion at a position deeper than a boundary between the first drift region and the second drift region.

19. The semiconductor device according to claim 5, wherein a plurality of the first active areas and a plurality of the insulating isolation structures are alternately arrayed in the second direction.

20. The semiconductor device according to claim 5, further comprising:
a second active area formed immediately below the insulating isolation structure in a thickness direction of the semiconductor chip,
wherein the drift region has a higher impurity concentration in the first active area than in the second active area.
